(19) United States
(12) Patent Application Publication
(10) Pub. No.: US 2026/0293006 A1
(43) Pub. Date: Sep. 24, 2026

(54) MOUNTING PLATE FOR SWITCH MODULE, SWITCH MODULE, AND POWER SUPPLY UNIT

(71) Applicant: CHANNEL WELL TECHNOLOGY CO., LTD., Taoyuan City (TW)

(72) Inventors: YEN-CHENG PAN, Taoyuan City (TW); BO-LUN LIN, Taoyuan City (TW); XUAN-CHENG LIU, Taoyuan City (TW)

(73) Assignee: CHANNEL WELL TECHNOLOGY CO., LTD., Taoyuan City (TW)

(21) Appl. No.: 19/208,628

(22) Filed: May 15, 2025

(30) Foreign Application Priority Data
Mar. 18, 2025 (TW) 114110044

(51) Int. Cl. H05K 5/02; G06F 1/26

(52) U.S. Cl. CPC H05K 5/0247; G06F 1/26

(57) ABSTRACT

A mounting plate for a switch module is provided, including: a first assembly and a second assembly. The first assembly has a first plane. The first plane is provided with at least one switch mounting hole. The second assembly has a second plane. The second plane is perpendicular to the first plane. The second plane is provided with at least one locking hole. The locking hole is perpendicular to the switch mounting hole. The present invention further provides a switch module, including the foregoing mounting plate and an electronic switch assembly arranged in the switch mounting hole. The present invention further proposes a power supply unit, including the foregoing switch module and a housing.

### CROSS-REFERENCE TO RELATED APPLICATION

This non-provisional application claims priority under 35 U.S.C. § 119(a) on Patent Application No(s). 114110044 filed in Taiwan, R.O.C. on Mar. 18, 2025, the entire contents of which are hereby incorporated by reference.

### BACKGROUND OF THE INVENTION

### 1. Field of the Invention

The present invention relates to a power supply unit for a computer, and more particularly, to a mounting plate for a switch module, a switch module having the foregoing mounting plate, and a power supply unit having the foregoing switch module.

### 2. Description of the Related Art

The power supply unit for a computer includes a circuit board, electronic elements arranged on the circuit board, a switch module electrically connected to the circuit board, and a housing accommodating the foregoing element. The switch module is locked to a surface of the housing, and then electronic connecting wires are arranged to be welded from the rear of the switch module to the circuit board in the housing.

Such an assembly process is not only complicated, and welding in the limited space of the housing is also quite difficult. If unexpected tin slag is generated during the welding, it is difficult to remove the tin slag and may easily cause device failure. In addition, lock holes are left on surfaces of the switch module locked to the housing. On the one hand, lack of beauty of the lock holes may reduce purchase intent of consumers, and may further cause psychological discomfort to a certain person. On the other hand, exposed locking screws affect flatness of the housing, causing excessive friction and vibration when the power supply unit is mounted to a card slot of a computer chassis, affecting quality of mounting.

### BRIEF SUMMARY OF THE INVENTION

Therefore, to resolve various problems of a power supply unit of a conventional computer, the present invention proposes a mounting plate for a switch module, a switch module, and a power supply unit.

To achieve the foregoing objective and other objectives, the present invention proposes a mounting plate for a switch module, including: a first assembly having a first plane, where the first plane is provided with at least one switch mounting hole; and a second assembly having a second plane, where the second plane is perpendicular to the first plane, the second plane is provided with at least one locking hole, and the locking hole is perpendicular to the switch mounting hole.

In an embodiment of the present invention, an edge of the first plane is provided with at least one notch.

In an embodiment of the present invention, the second assembly is provided with a give-way hole.

The present invention further proposes a switch module, including: the foregoing mounting plate for a switch module; and an electronic switch assembly arranged in the switch mounting hole.

In an embodiment of the present invention, the electronic switch assembly is a power switch or a socket switch.

In an embodiment of the present invention, the first plane is provided with two switch mounting holes, and the electronic switch assembly includes a power switch and a socket switch which are respectively arranged in the two switch mounting holes.

In an embodiment of the present invention, the switch module further includes a circuit board and an electronic wire set. The electronic wire set connects the electronic switch assembly and the circuit board.

The present invention further proposes a power supply unit, including: the foregoing switch module; and a housing including: a base including a bottom wall, a first direction side wall, and a first extension portion, where the first direction side wall is connected to the bottom wall, the first extension portion is perpendicularly connected to the first-direction side wall, the first assembly of the mounting plate is arranged parallel to the first direction side wall, and the second assembly of the mounting plate is locked parallel to the first extension portion; and an upper cover covering the first extension portion.

Through the mounting plate for a switch module, the switch module, and the power supply unit of the present invention, the lock hole originally existing on the mounting surface of the mounting plate may be covered, so that the lock hole is hidden in the housing of the power supply unit. Therefore, the power supply unit may contact other apparatus through a smooth and flat surface and may move smoothly, thereby avoiding excessive friction and vibration, providing excellent mounting quality, realizing a more aesthetically pleasing appearance, and reducing a possibility of causing psychological discomfort to a specific person.

### BRIEF DESCRIPTION OF THE DRAWINGS

FIG. 1 is a schematic assembly diagram of a switch module according to an embodiment of the present invention.

FIG. 2 is a three-dimensional schematic diagram of a switch module according to an embodiment of the present invention.

FIG. 3 is a schematic diagram of a switch module mounted to a first direction side wall according to an embodiment of the present invention.

FIG. 4 is a partially enlarged schematic view of FIG. 3 from another perspective.

FIG. 5 is a schematic diagram showing completed mounting of FIG. 3.

FIG. 6 is a schematic diagram of an appearance of a power supply unit according to an embodiment of the present invention.

### DETAILED DESCRIPTION OF THE INVENTION

To fully understand the present invention, the present invention is described in detail through the following specific embodiments and the accompanying drawings. A person skilled in the art can understand the objectives, features, and effects of the present invention from the content disclosed in this specification. It should be noted that the present invention may be implemented or applied through other different specific embodiments, and various details in this specification may also be modified and changed based on different viewpoints and applications without departing from the spirit of the present invention. The relevant technical content of the present invention is to be further described in detail through the following implementations, but the disclosed content is not intended to limit the scope of the patent application of the present invention. The description is as follows.

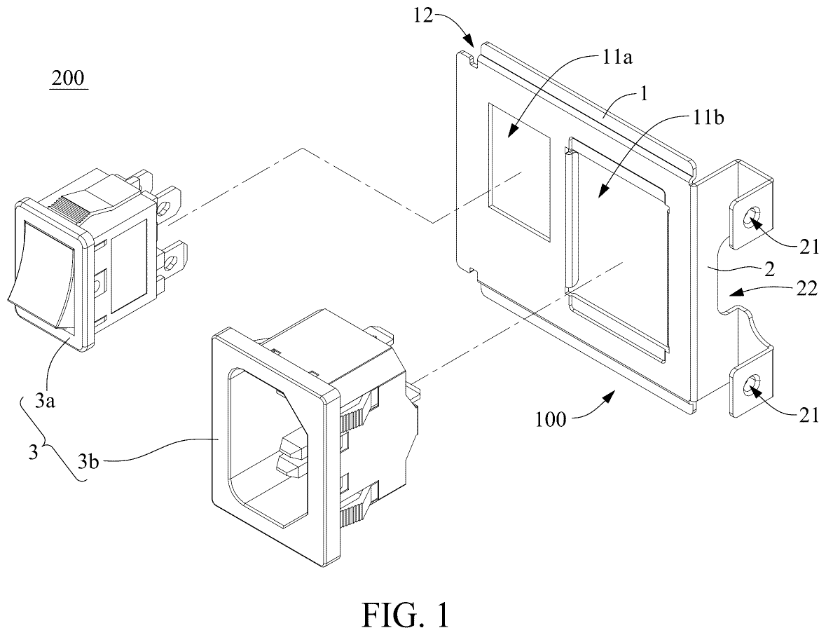

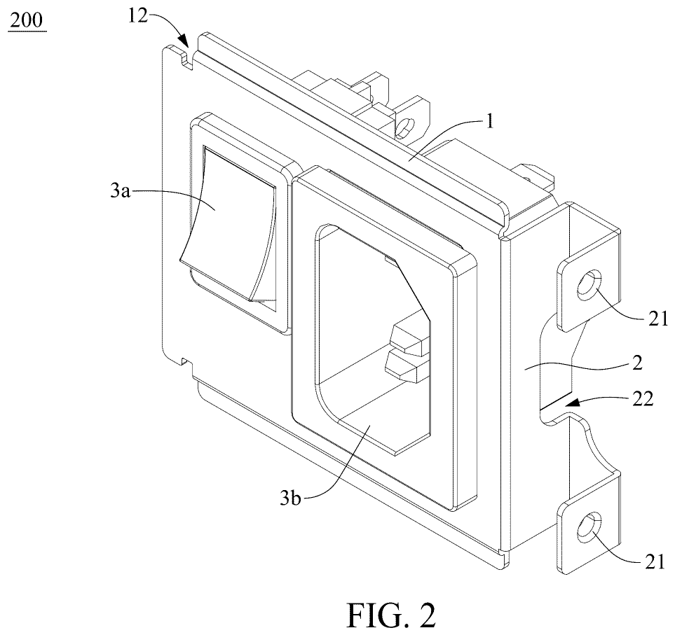

As shown in FIG. 1 and FIG. 2, a mounting plate 100 for a switch module 200 according to an embodiment of the present invention includes a first assembly 1 and a second assembly 2.

The first assembly 1 has a first plane. The first plane is provided with at least one switch mounting hole. In this embodiment, the first plane is provided with two switch mounting holes 11a and 11b, which are respectively configured to allow mounting of a power switch 3a and a socket switch 3b. However, the present invention is not limited thereto. The first plane may be provided with only one or more switch mounting holes, to meet a power switch mounting requirement of the switch module 200.

The second assembly 2 has a second plane. The second plane is perpendicular to the first plane of the first assembly 1. The second plane is provided with at least one locking hole 21. An opening direction of the locking hole 21 is perpendicular to an opening direction of the switch mounting holes 11a and 11b.

Such a mounting plate 100, together with an electronic switch assembly 3 arranged in the switch mounting holes 11a and 11b or at least one thereof, and may be combined to form the switch module 200.

The electronic switch assembly 3 is, for example, the power switch 3a or the socket switch 3b. The power switch 3a refers to a switch that provides power connection or disconnection, and the socket switch 3b refers to a switch that provides a power connection interface for a socket. In this embodiment, the electronic switch assembly 3 includes a power switch 3a and a socket switch 3b which are respectively arranged in the two switch mounting holes 11a and 11b.

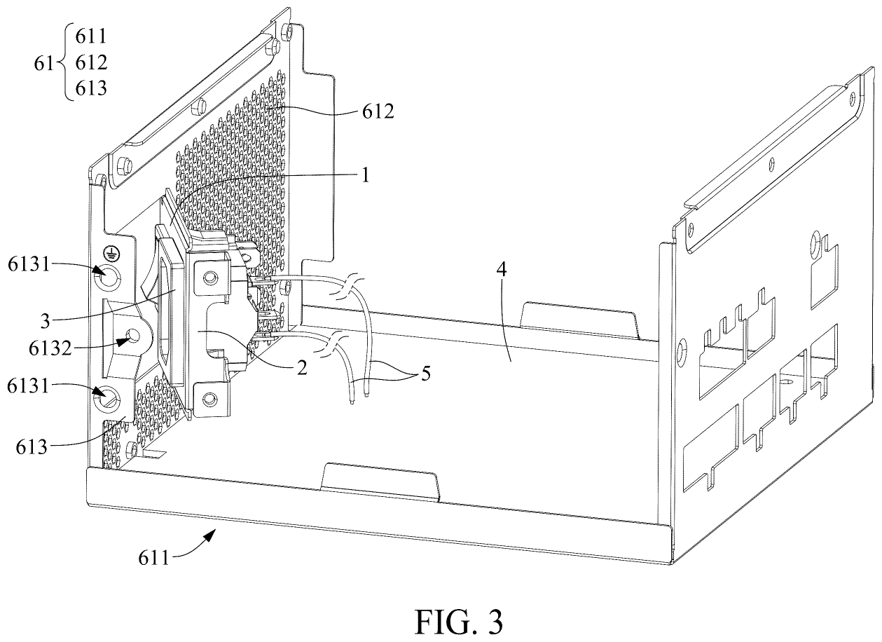

As shown in FIG. 3, the switch module 200 may further optionally include a circuit board 4 and an electronic wire set 5. The electronic wire set 5 connects one or more electronic switch assemblies 3 and the circuit board 4. The electronic switch assembly 3 may be connected to the circuit board 4 in advance through the electronic wire set 5, without the need to perform welding in a housing 6 of a power supply unit 300.

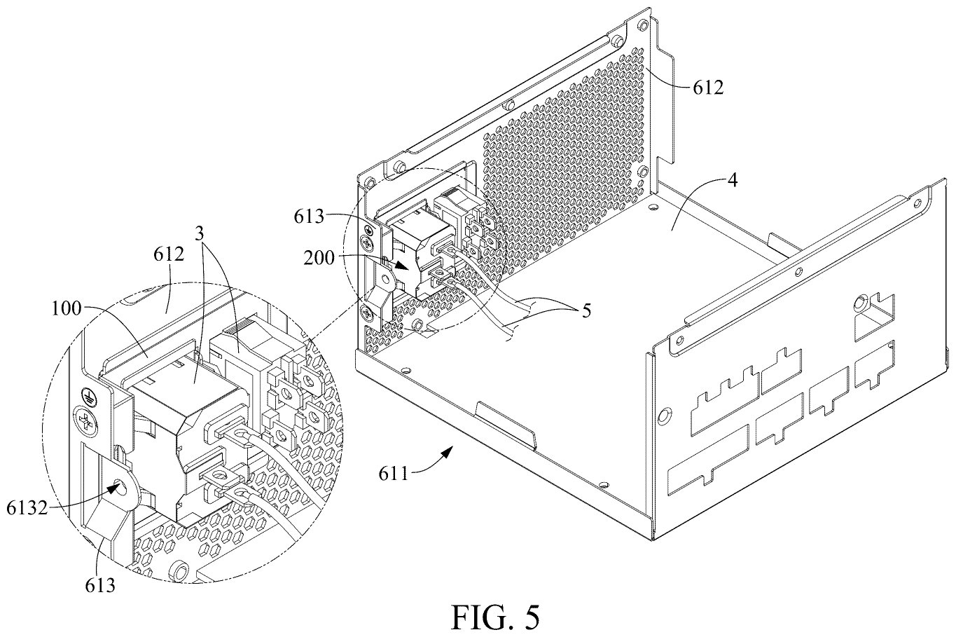

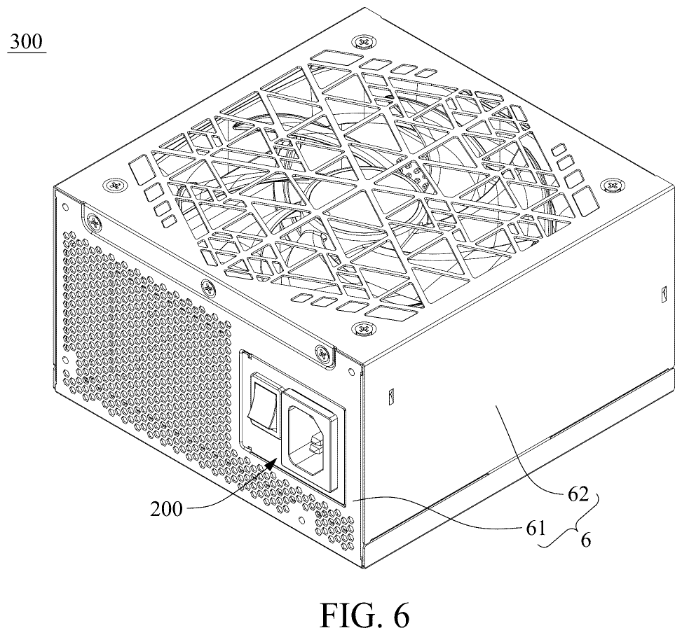

Next, how to mount the switch module 200 to form the power supply unit 300 is described. As shown in FIG. 5 and FIG. 6, the power supply unit 300 includes the switch module 200 and the housing 6. The housing 6 includes a base 61 and an upper cover 62.

The base 61 includes a bottom wall 611, a first direction side wall 612, and a first extension portion 613. The first direction side wall 612 is connected to the bottom wall 611, and the first extension portion 613 is perpendicularly connected to the first direction side wall 612.

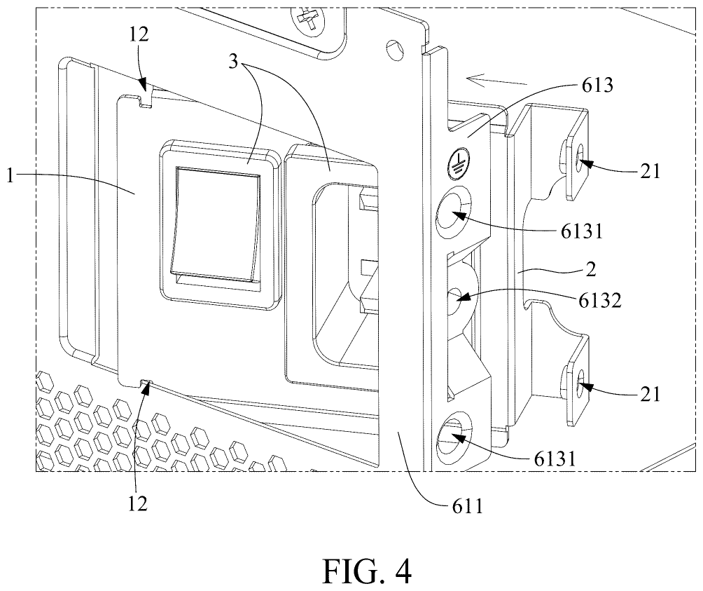

As shown in FIG. 3 and FIG. 4, during the mounting, the circuit board 4 may be optionally arranged above the bottom wall 611. Then the mounting plate 100 mounted with the electronic switch assembly 3 is slid obliquely into a reserved hole from the rear of the first direction side wall 612, so that the first assembly 1 of the mounting plate 100 is arranged parallel to the first direction side wall 612, and the second assembly 2 of the mounting plate 100 is locked parallel to the first extension portion 613. The locking hole 21 is directly opposite to a lock hole 6131 of the first extension portion 613. A situation after the locking is completed is shown in FIG. 5. In this case, the mounting plate 100/the switch module 200 is fixed to the base 61 through locking at the first extension portion 613.

Next, the upper cover 62 covers the first extension portion 613 to form a hexahedral structure. Since the first extension portion 613 is only a vertical extension of a small portion of the first direction side wall 612, mounting of elements inside the housing 6 is not affected. However, through the covering of the upper cover 62, the mounting plate 100 and the locking hole 21 and the lock hole 6131 of the first extension portion 613 may be just covered, so that these holes are not directly exposed. Therefore, the power supply unit 300 of the present invention may contact other apparatus through a smooth and flat surface and may move smoothly, thereby avoiding excessive friction and vibration, providing excellent mounting quality, realizing a more aesthetically pleasing appearance, and reducing a possibility of causing psychological discomfort to a specific person.

Further, in this embodiment, as shown in FIG. 4, an edge of the first plane is provided with at least one notch 12. The notch 12 enables the first assembly 1 to elastically deform and enter the reserved hole of the first direction side wall 612, thereby facilitating assembly.

Further, in this embodiment, as shown in FIG. 1, the second assembly 2 is provided with a give-way hole 22. The give-way hole 22 is located between the two locking holes 21 and is configured to allow a grounding element to pass through. In detail, as shown in FIG. 5, the grounding element, such as a grounding screw, may pass through the give-way hole 22 through the grounding hole 6132 of the first extension portion 613 to directly contact the electronic switch assembly 3, so that the electronic switch assembly 3 and the housing 6 are grounded, and a more stable locking effect is provided.

In addition, in this embodiment, the second assembly 2 is in the form of a bent sheet metal member, so that the second assembly 2 has an elastic force to push against the first extension portion 613, and the second assembly 2 and the first extension portion 613 are actively fitted. However, the present invention is not limited thereto. The second assembly 2 may also be a single-piece planar structure. The entire second assembly 2 only has the second plane, and the entire second assembly 2 is vertically connected to the first assembly 1.

The present invention has been disclosed in the above with embodiments. However, a person skilled in the art should understand that the embodiment is only used to illustrate the present invention, and should not be interpreted as a limitation on the scope of the present invention. It should be noted that all changes and substitutions equivalent to the embodiment should be considered to fall within the scope of the present invention. Therefore, the protection scope of the present invention is subject to the scope defined by the patent claims.

What is claimed is:

1. A mounting plate for a switch module, comprising:
a first assembly having a first plane, wherein the first plane is provided with at least one switch mounting hole; and
a second assembly having a second plane, wherein the second plane is perpendicular to the first plane, the second plane is provided with at least one locking hole, and the locking hole is perpendicular to the switch mounting hole.

2. The mounting plate for a switch module according to claim 1, wherein an edge of the first plane is provided with at least one notch.

3. The mounting plate for a switch module according to claim 1, wherein the second assembly is provided with a give-way hole.

4. A switch module, comprising:
the mounting plate for a switch module according to claim 1; and
an electronic switch assembly arranged in the switch mounting hole.

5. The switch module according to claim 4, wherein the electronic switch assembly is a power switch or a socket switch.

6. The switch module according to claim 4, wherein the first plane is provided with two switch mounting holes, and the electronic switch assembly comprises a power switch and a socket switch which are respectively arranged in the two switch mounting holes.

7. The switch module according to claim 4, further comprising a circuit board and an electronic wire set, wherein the electronic wire set connects the electronic switch assembly and the circuit board.

8. A power supply unit, comprising:
the switch module according to claim 4; and
a housing, comprising:
a base comprising a bottom wall, a first direction side wall, and a first extension portion, wherein the first direction side wall is connected to the bottom wall, the first extension portion is perpendicularly connected to the firs direction side wall, the first assembly of the mounting plate is arranged parallel to the first direction side wall, and the second assembly of the mounting plate is locked parallel to the first extension portion; and
an upper cover covering the first extension portion.
